(19) United States
(12) Patent Application Publication
(10) Pub. No.: US 2025/0373994 A1
(43) Pub. Date: Dec. 4, 2025

(54) SPEAKER MONITORING

(71) Applicant: Apple Inc., Cupertino, CA (US)

(72) Inventors: Reza GHAFFARIVARDAVAGH, San Jose, CA (US); Mohammad Javad KHODAEI, Santa Clara, CA (US); Onur I. ILKORUR, Santa Clara, CA (US); Thomas M. JENSEN, San Francisco, CA (US); Matthew A. DONARSKI, San Francisco, CA (US); Andrew P. BRIGHT, Los Gatos, CA (US); Christopher WILK, Los Gatos, CA (US)

(21) Appl. No.: 19/215,312

(22) Filed: May 21, 2025

Related U.S. Application Data
(60) Provisional application No. 63/656,099, filed on Jun. 4, 2024.

(51) Int. Cl. H04R 29/00

(52) U.S. Cl. CPC H04R 29/001

(57) ABSTRACT

Aspects of the subject technology relate to monitoring one or more characteristics of a speaker, such as an excursion, rocking amplitude, or force factor of the speaker. The monitoring may be performed without the use or presence of a sensor that directly measures these speaker characteristics. The monitoring may include determining the excursion, rocking amplitude, or force factor based on an intermodulation distortion that occurs when an ultrasonic tone and one or more human audible tones are output by the speaker concurrently, and/or based on a phase difference between peaks in a speaker current and a speaker voltage.

### CROSS REFERENCE TO RELATED APPLICATIONS

This application claims the benefit of priority to U.S. Provisional Patent Application No. 63/656,099, entitled, “SPEAKER MONITORING”, filed on Jun. 4, 2024, the disclosure of which is hereby incorporated herein in its entirety.

### TECHNICAL FIELD

The present description relates generally to acoustic devices including, for example, to speaker monitoring.

### BACKGROUND

Speaker control systems often limit the motion of a speaker diaphragm, to prevent damage to the speaker.

### BRIEF DESCRIPTION OF THE DRAWINGS

Certain features of the subject technology are set forth in the appended claims. However, for purpose of explanation, several aspects of the subject technology are set forth in the following figures.

FIG. 1 illustrates a perspective view of an example electronic device having a speaker in accordance with various aspects of the subject technology.

FIG. 2 illustrates a cross-sectional view of a portion of an example electronic device having a speaker in accordance with various aspects of the subject technology.

FIG. 3 illustrates a cross-sectional view of a portion of a speaker in accordance with various aspects of the subject technology.

FIG. 4 illustrates an example current that includes intermodulation distortion (IMD) in accordance with various aspects of the subject technology.

FIG. 5 illustrates an example of rocking motion of a sound-generating element of a speaker in accordance with various aspects of the subject technology.

FIG. 6 illustrates a cross-sectional view of a portion of the speaker of FIG. 3, in the presence of rocking in accordance with various aspects of the subject technology.

FIG. 7 illustrates example third order IMD peaks in an output current from a speaker experiencing rocking in accordance with various aspects of the subject technology.

FIG. 8 illustrates an example architecture for performing speaker monitoring in accordance with various aspects of the subject technology.

FIG. 9 illustrates an example current that includes intermodulation distortion (IMD) in the presence of an impact in a speaker in accordance with various aspects of the subject technology.

FIG. 10 illustrates a flow chart of illustrative operations that may be performed for speaker monitoring in accordance with various aspects of the subject technology.

FIG. 11 illustrates a cross-sectional view of a portion of a speaker in accordance with various aspects of the subject technology

FIG. 12A illustrates an excursion-phase difference map in accordance with various aspects of the subject technology.

FIG. 12B illustrates an inductance-excursion map in accordance with various aspects of the subject technology.

FIG. 13 illustrates another flow chart of illustrative operations that may be performed for speaker monitoring in accordance with various aspects of the subject technology.

FIG. 14 illustrates another flow chart of illustrative operations that may be performed for speaker monitoring in accordance with various aspects of the subject technology.

FIG. 15 illustrates a flow chart of illustrative operations that may be performed for speaker protection in accordance with various aspects of the subject technology.

FIG. 16 illustrates an electronic system with which one or more implementations of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

A sound-generating element, such as a diaphragm, of a speaker may move responsive to an input audio signal, to generate sound for the speaker. The input audio signal may be delivered to the speaker in the form of a current through a voice coil of the speaker. The amount of motion of the sound-generating component that results from a particular input audio signal may be referred to an excursion of the sound-generating component. For example, the excursion of a speaker at a given time may be the distance of the sound-generating component, at that given time, from (e.g., above or below) a neutral (rest) position of the sound-generating component. In some use cases, an undesirable rocking of the sound-generating element can also occur. For example, rocking may occur when one portion of the sound-generating element moves more or less than other portions of the sound-generating component. It can be helpful during manufacturing and/or assembly of a speaker, and/or during use of a speaker, to be able to monitor speaker characteristics, such as the excursion and/or rocking of the sound-generating component.

For example, excursion and/or rocking measurements made during manufacturing and/or assembly can be used for speaker calibration and/or to set speaker protection parameters. Excursion and/or rocking measurements made during real-time use of a speaker (e.g., using a laser sensor or based on a physical model of the speaker) may be helpful for real-time speaker protection, and/or to correct for speaker system non-linearities (e.g., non-linearities in the stiffness of the speaker surround, the force factor, the inductance, the speaker materials, the airflow, and/or the sound pressure and/or propagation within or around the speaker) that cause rocking and/or other undesirable effects on the operations of the speaker. However, it can be difficult to measure the excursion and/or rocking of a speaker without introducing a sensor, such as a laser sensor or a camera, into the speaker to directly measure the location and/or motion of the sound-generating element of the speaker. An additional sensor to directly measure the location and/or motion of the sound-generating element of the speaker can increase the cost and/or complexity of manufacturing, can reduce the available space in the speaker for motion of the sound-generating element, and/or can result in an increase is size of the speaker system, which can be particularly undesirable or unfeasible in compact devices, such as portable electronic devices.

In some manufacturing and/or assembly operations, excursion and/or rocking for a limited number of samples per build of a speaker can be measured using a separate external sensor (e.g., a laser sensor that directly measures the position of one or more locations on the sound-generating component by projecting a laser beam onto the sound-generating component and sensing a reflection of the laser beam from the sound-generating component), and settings from these limited number of samples applied to all of the speakers of that build. However, this can be blind to any module variations that occur after engineering builds.

In some speaker systems, estimates of speaker characteristics such as excursion can be made using physical models of the speaker. However, inadequate physical model predictors are often a source of additional challenges for loudspeaker control algorithms. For example, time-invariant prediction models that are not aware of the current operational state of the speaker system cannot adequately model the time varying changes of the speaker system, such as power compression and loss of acoustic sensitivity. For this reason, time-invariant prediction models are often tuned for a worst case scenario operating condition, which can have the undesired effect of providing unnecessary and/or unused safety margin, and overprotection of the speaker system under many, if not most, operating conditions. Physical speaker models may also fail to adequately capture part-to-part variations resulting from the manufacturing and/or assembly processes for speaker systems and/or devices in which speaker systems are implemented.

Aspects of the subject technology may provide the ability to monitor speaker excursion, rocking, and/or a force factor of the speaker, without the use of an additional sensor in the speaker to directly measure the location of the sound-generating component. For example, the speaker excursion, rocking, and/or force factor may be determined based on an effect of an intermodulation distortion (IMD) on the current passing through the speaker (e.g., through the voice coil). For example, the IMD generated between a human audible frequency and an ultrasonic frequency that are concurrently output by the speaker may generate second order and third order peaks in the current that can be used to derive the excursion and rocking amplitudes, respectively. The measured IMD information in the speaker current can also be used to determine the force factor. The determined excursion, rocking amplitudes, and/or force factor can be used for control of the speaker, including for speaker protection and/or non-linearity corrections.

An illustrative electronic device including a speaker is shown in FIG. 1. In the example of FIG. 1, electronic device 100 has been implemented using a housing that is sufficiently small to be portable and carried or worn by a user (e.g., electronic device 100 of FIG. 1 may be a handheld electronic device such as a tablet computer or a cellular telephone or smart phone or a wearable device such as a smart watch, a pendant device, a headlamp device, head mountable device, or the like). In the example of FIG. 1, electronic device 100 includes a display such as display 110 mounted on the front of a housing 106. Electronic device 100 may include one or more input/output devices such as a touch screen incorporated into display 110, a button, a switch, a dial, a crown, and/or other input output components disposed on or behind display 110 or on or behind other portions of housing 106. Display 110 and/or housing 106 may include one or more openings to accommodate a button, a speaker, a light source, or a camera (as examples).

In the example of FIG. 1, housing 106 includes an opening 108. For example, opening 108 may form a port for an audio component. In the example of FIG. 1, the opening 108 forms a speaker port for a speaker 114 disposed within the housing 106. In this example, the speaker 114 is aligned with the opening 108 to project sound through the opening 108. In other implementations, the speaker 114 may be offset from the opening 108, and sound from the speaker may be routed to and through the opening 108 by one or more internal device structures.

In the example of FIG. 1, display 110 also includes an opening 112. For example, opening 112 may form a port for an audio component. In the example of FIG. 1, the opening 112 forms a speaker port for a speaker 114 disposed within the housing 106 and behind a portion of the display 110. In this example, the speaker 114 is offset from the opening 112, and sound from the speaker may be routed to and through the opening 112 by one or more device structures. In other implementations, the speaker 114 may be aligned with a corresponding opening 108 or opening 112.

In various implementations, the housing 106 and/or the display 110 may also include other openings, such as openings for one or more microphones, one or more pressure sensors, one or more light sources, or other components that receive or provide signals from or to the environment external to the housing 106. Openings such as opening 108 and/or opening 112 may be open ports or may be completely or partially covered with a permeable membrane or a mesh structure that allows air and/or sound to pass through the openings. Although two openings (e.g., opening 108 and opening 112) are shown in FIG. 1, this is merely illustrative. One opening 108, two openings 108, or more than two openings 108 may be provided on the one or more sidewalls of the housing 106, on a rear surface of housing 106 and/or a front surface of housing 106. One opening 112, two openings 112, or more than two openings 112 may be provided in the display 110. In some implementations, one or more groups of openings in housing 106 and/or groups of openings 112 in display 110 may be aligned with a single port of an audio component within housing 106. Housing 106, which may sometimes be referred to as a case, may be formed of plastic, glass, ceramics, fiber composites, metal (e.g., stainless steel, aluminum, etc.), other suitable materials, or a combination of any two or more of these materials.

The configuration of electronic device 100 of FIG. 1 is merely illustrative. In other implementations, electronic device 100 may be a computer such as a computer that is integrated into a display such as a computer monitor, a laptop computer, a media player, a gaming device, a navigation device, a computer monitor, a television, a smart speaker, a headphone, an earbud, or other electronic equipment. In some implementations, electronic device 100 may be provided in the form of a wearable device such as a smart watch. In one or more implementations, housing 106 may include one or more interfaces for mechanically coupling housing 106 to a strap or other structure for securing housing 106 to a wearer.

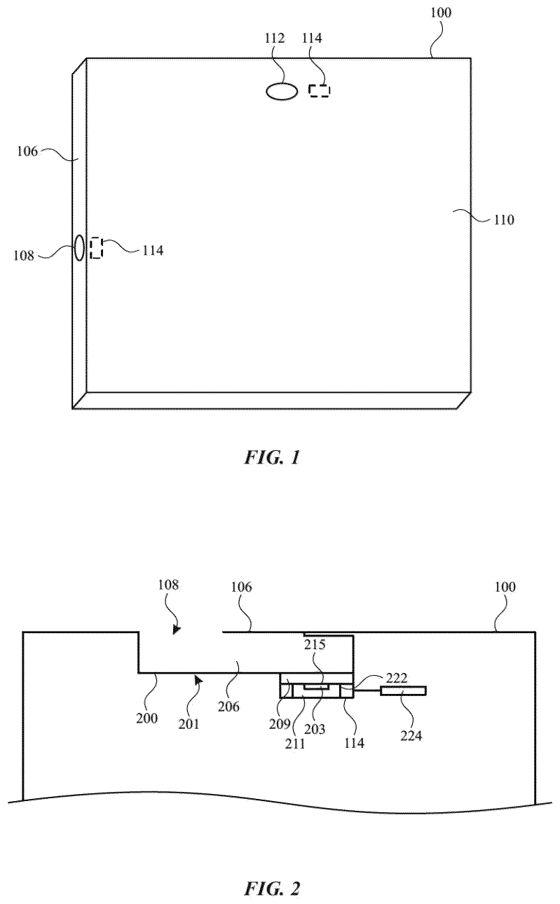

FIG. 2 illustrates a cross-sectional side view of a portion of the electronic device 100 including a speaker 114. In this example, the speaker 114 may include a front volume 209 and a back volume 211. The front volume 209 and the back volume 211 may be separated by a sound-generating element 215 (e.g., a diaphragm mounted to a voice coil, or an actuatable component of a microelectromechanical systems (MEMS) speaker). The front volume 209 may be fluidly and acoustically coupled (e.g., directly or via an acoustic duct 206 in the example of FIG. 2) to the opening 108 in the housing 106. In one or more implementations, the acoustic duct 206 may be formed by a speaker housing 200 of a speaker module 201 in which the speaker 114 is disposed. In one or more other implementations, the acoustic duct 206 may be formed, entirely or in part, by one or more other device structures that guide sound generated by the speaker 114 through the opening 108 to the environment external to the housing 106. In one or more other implementations, the speaker 114 may be mounted directly adjacent and/or aligned with the opening 108 so that sound from the speaker 114 is directed through the opening with or without an acoustic duct 206 or other guiding structure. In the example of FIG. 2, the speaker 114 is spatially offset from the opening 108. However, in one or more other implementations, the speaker 114 may be aligned with the opening 108 (e.g., and fluidly and acoustically coupled to the opening 108 directly or via an acoustic duct). In one or more implementations, the speaker 114 may be a compact speaker having a cross-sectional area of less than, for example one thousand square millimeters (mm²), six hundred mm², two hundred mm², less than one hundred mm², or less than fifty mm². In one or more other implementations, the speaker 114 may be a relatively larger speaker having a cross-sectional width (e.g., a diameter) of between three inches and five inches, between five inches and seven inches, or greater than seven inches.

The electronic device 100 may include control circuitry, such as speaker circuitry 222 and/or device circuitry 224. In the example of FIG. 2, the speaker 114 includes the speaker circuitry 222. The speaker circuitry 222 may include, for example, a voice coil 203, a magnet, and/or other speaker hardware (e.g., one or more amplifiers, current sensors, etc.). In one or more implementations, the electronic device 100 may also include other circuitry, such as device circuitry 224. Device circuitry 224 may include one or more processors, memory, acoustic components, haptic components, mechanical components, electronic components, or any other suitable components of an electronic device. In one or more implementations, the speaker circuitry 222 and/or the device circuitry 224 may include a current meter (e.g., an ammeter or Hall effect sensor) for measuring an amount of current flowing through the speaker (e.g., through the voice coil 203).

In accordance with aspects of the subject disclosure, the measured current can be used to determine one or more speaker characteristics, such as an excursion, a rocking characteristic, and/or a force factor (e.g., a motor strength of the speaker, which may be referred to as “BL”, which may represent the magnetic field, B, in a gap between the magnets of the speaker multiplied by the length, L, of the voice coil 203) of the speaker 114.

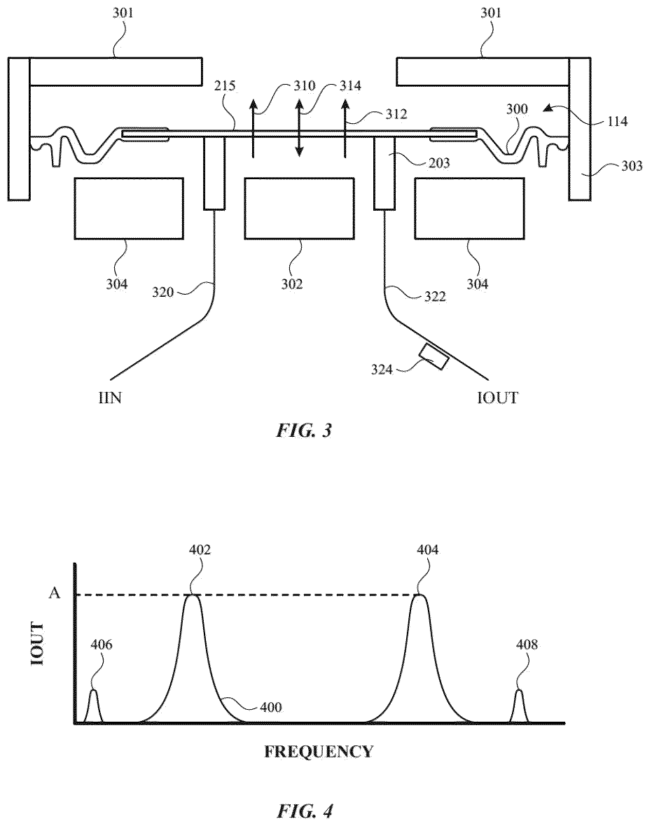

FIG. 3 illustrates a cross-sectional view of the speaker 114 in accordance with one or more implementations. As shown, an input current, Iin, may be provided to the voice coil 203 (e.g., from the device circuitry 224, such as via a conductive element 320, such as a wire, a flexible printed circuit, or other conductive element). For example, the input current, Iin, may be generated by the device circuitry 224 based on audio content to be output by the speaker 114. The audio content may include test content for making speaker measurements during manufacturing and/or assembly of the speaker 114 and/or the electronic device 100, or may include media content (e.g., music, an audio track corresponding to video content, a podcast, a system sound or application sound, or any other media content) for audio output to a user of the electronic device 100. For example, the input current, Iin, may include variations corresponding to the audio content, such that the variations cause the sound-generating component to move (e.g., as indicated by arrows 314) to generate an audio output 310 including the audio content. The audio output 310 may be output from the speaker 114 in a human audible frequency range (e.g., a frequency range between twenty Hertz (HZ) and twenty kilohertz (kHz)), or in a subrange of the human audible frequency range (e.g., between fifty Hz and two kHz). As examples, the audio output 310 may include a single tone in the human audible frequency range, a sweep through multiple tones in the human audible frequency range, and/or media content having one or more (e.g., many) tones that are output concurrently with each other.

As indicated by the arrows 314, the sound-generating element 215 may move responsive to the input current, Iin, provided to the voice coil 203 to generate the audio output 310. For example, a magnetic field generated by the current flowing through the voice coil 203 may interact with one or more fixed magnets (e.g., a fixed magnet 302 that is partially within the space formed by the voice coil, and/or a fixed magnet 304 disposed outside the voice coil) to cause motion of the voice coil 203, and thereby the sound-generating element 215 coupled thereto. As shown, a flexible surround 300 may movably attach the sound-generating element 215 to a fixed support structure 303. The flexible surround 300 may allow the sound-generating element 215 to generally move in an up-down motion as indicated by the arrows 314. The flexible surround 300, the voice coil, and the input current, Iin, may be designed to cause motion (e.g., up and down or back and forth motion) of the sound-generating element 215 along a single dimension (e.g., as indicated by the arrows 314).

In one or more implementations, it may be desirable to limit the motion of the sound-generating element 215, such as to protect the speaker 114, by preventing excursions of the sound-generating element 215 that would cause the sound-generating element 215 or the voice coil 203 to impact the fixed magnet 302, the fixed magnet 304, a cover layer 301 (e.g., a portion of the speaker housing 200 or a portion of the housing 106 of the electronic device 100), or any other fixed structure of the speaker 114 or the electronic device 100. In one or more implementations, it may be desirable to be able to tune the input current, Iin, to account for measurements of the excursion of the sound-generating element 215, measurements of rocking of the sound-generating element 215, and/or measurements of a force factor resulting from the input current, Iin, during real-time use of the speaker 114 (e.g., by an end user).

In one or more implementations, the input current, Iin, may include a portion configured to cause the sound-generating element 215 to generate another output including one or more tones that are configured as human inaudible tones, concurrently with the audio output 310. As examples, tones that are configured as human inaudible tones may be tones in a human inaudible frequency range (e.g., an ultrasonic frequency range) or tones in a human audible frequency range that are below a human audible threshold amplitude (e.g., a zero decibel threshold or a variable threshold that depends on the audio output 310, as discussed in further detail hereinafter). For example, in one or more implementations, the input current, Iin, may include a portion configured to cause the sound-generating element 215 to generate an ultrasound output 312 concurrently with the audio output 310. The ultrasound output 312 may include one or more ultrasonic tones in an ultrasonic frequency range (e.g., above 20 kHz, such as at or near 21 kHz).

Adding one or more tones configured as human inaudible tones, such as the ultrasound output 312, to the audio output 310 may cause an intermodulation distortion (IMD) in the output of the speaker 114. However, because the human inaudible tones are inaudible to a user (e.g., because the ultrasound output 312 is outside of the human audible range, and at a frequency significantly higher than the audio output 310), the IMD output of the speaker 114 may be inaudible to a user of the speaker 114 and/or the electronic device 100. The amount or amplitude of the IMD effect of combining the ultrasound output 312 (or another human inaudible tone) with the audio output 310 in the output of the speaker 114 may be dependent on the motion(s) of the sound-generating element 215. For example, when IMD is present and the speaker 114 is operating with a large excursion, the amplitude of the IMD effect at some frequencies may be (e.g., proportionally) larger. As another example, when IMD is present and the sound-generating element 215 is rocking, the amplitude of the IMD effect at other frequencies may be (e.g., proportionally) larger. This IMD effect on the output of the speaker 114 is generated by additional motions of the sound-generating element 215 (e.g., additional to any primary motions for generating the audio output 310), and these additional motions of the sound-generating component may, in turn, affect the current, Iout, that is output from the speaker 114 (e.g., output via a conductive element 322, such as a wire, a flexible printed circuit, or other conductive element). As shown, a current meter 324 (e.g., an ammeter, Hall effect sensor, and/or shunt resistor) may be provided (e.g., within the speaker or external to the speaker) that measures the output current, Iout, from the speaker 114.

FIG. 4 illustrates an example of an effect, on the output current, Iout, of the IMD generated by the combined audio output 310 and ultrasound output 312. For example, FIG. 4 may represent a (e.g., normalized) frequency transform 400 (e.g., a Fourier transform, such as a Fast Fourier Transform (FFT)) of the current, Iout, in frequency space. As shown, the output current, Iout, may include one or more first peaks, such as a peak 402 and a peak 404. For example, the peaks 402 and 404 may be located at the frequency of the ultrasound output 312 minus and plus, respectively, the frequency of the audio output 310. For example, the peaks 402 and 404 may be second order IMD peaks. In the subject system, for sufficiently high frequency ultrasonic tones (e.g., because the ultrasound output 312 is at a significantly higher, such a five times, ten times, or one hundred times higher, frequency than the audio output 310), the energy in the current at the ultrasonic output frequency plus or minus the audio output frequency may be proportional to the (e.g., maximum) excursion. Accordingly, a measurement (e.g., by the current meter 324) of the amplitude, A, of the peak 402 and/or the peak 404 (e.g., the second order IMD peaks) in the output current, Iout, (e.g., scaled by a gain factor, such as an experimentally determined gain factor, as discussed in further detail hereinafter) may provide a measurement of the excursion of the speaker (e.g., of the sound-generating element 215). For example, the excursion of the speaker (e.g., the sound-generating element 215) at a time, t, may be given by xₘₐₓ*sin (2πf₀t), where f₀ is the frequency of the human audible tone, and xₘₐₓ is proportional to the amplitude, A. For example, xₘₐₓ may be equal to gain*A, where gain is an experimentally determined gain factor. The gain factor may be specific to a particular speaker or speaker type or category.

As shown by the frequency transform 400 of the output current Iout of FIG. 4, the output current, Iout, may also include one or more second peaks, such as peaks 406 and 408. For example, the peaks 406 and 408 may be located at the frequency of the ultrasound output 312 minus and plus, respectively, twice the frequency of the audio output 310. For example, the peaks 406 and 408 may be third order IMD peaks.

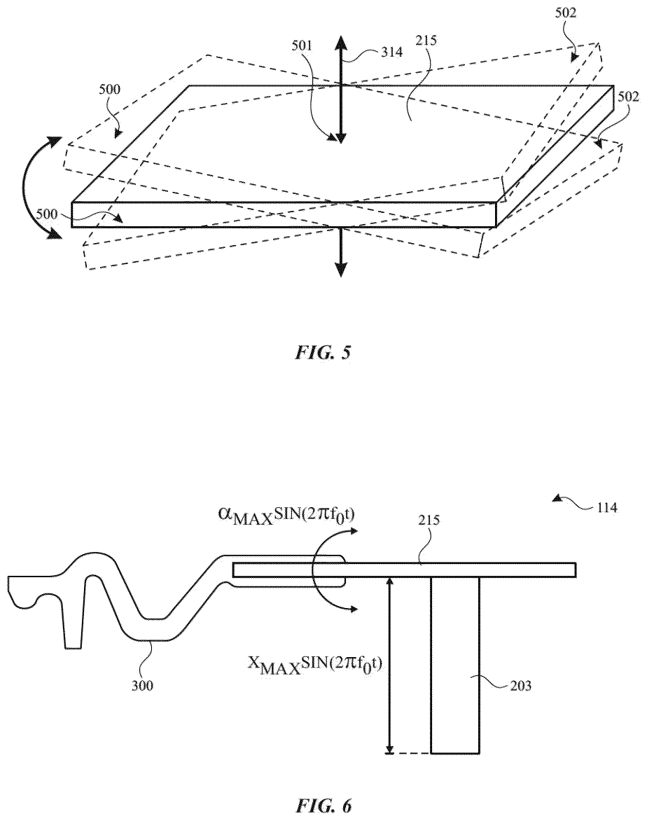

FIG. 5 illustrates an example of a rocking motion of the sound-generating element 215. As shown in FIG. 5, when rocking occurs, some portions of the sound-generating element 215 (e.g., one or more edges and/or one or more corners) move differently that other portions (e.g., one or more opposing edges and/or one or more other corners) of the sound-generating element 215. Rocking of the sound-generating element 215 may occur in one dimension (e.g., with rotation of the sound-generating element 215 about a line that passes through the center 501 of the sound-generating element 215) or two dimensions (e.g., with rotations of the sound-generating element 215 about two perpendicular lines that intersect at the center 501 of the sound-generating element 215). In the example of FIG. 5, a corner 500 of the sound-generating element 215 moves upward while another corner 502 moves downward. The rocking motion of the sound-generating element 215 may occur in addition to the overall excursion, as indicated by the arrows 314, of the sound-generating element 215 for generation of the audio output 310 (e.g., and/or the ultrasound output 312). For example, the center 501 of the sound-generating element 215 may move up and down to generate an output for the speaker 114, while one or more edges and/or corners (e.g., corners 500 and 502) rotate about the center 501 due to the rocking motion.

In the subject system, for sufficiently high frequency ultrasonic tones (e.g., because the ultrasound output 312 is at a significantly higher, such a five times, ten times, or one hundred times higher, frequency than the audio output 310), the energy in the current at ultrasonic output frequency plus or minus twice the audio output frequency) may be proportional to the (e.g., maximum) rocking amplitude of the sound-generating element 215.

Accordingly, a measurement (e.g., by the current meter 324) of the peak 406 and/or the peak 408 (e.g., the third order IMD peaks) in the output current, Iout, (e.g., scaled by a gain factor, such as an experimentally determined gain factor, as discussed in further detail hereinafter) may provide a measurement of the rocking of the speaker. For example, the rocking amplitude of the speaker (e.g., the sound-generating element 215) at a time, t, may be given by aₘₐₓ*sin (2πf₀t), where f₀ is the frequency of the human audible tone, and aₘₐₓ is proportional to the measurement of the peak 406 and/or the peak 408. In one or more implementations, the measurement of the peak 406 and/or the peak 408 may be a measurement of the amplitude of the peak 406 and/or the peak 408, or may be a measurement of a peak-to-dip amplitude of the peak 406 and/or the peak 408 and an associated dip that may appear in the output current, Iout.

For example, FIG. 7 illustrates an example in which the third order IMD peaks in the output current, Iout, may each be adjacent to an associated dip in the output current when rocking is present. In the example of FIG. 7, the third order IMD amplitudes (e.g., resulting from the combination of the ultrasonic frequency signal plus twice the frequency of the audio content in the input signal) in the output current, Iout, as a function of frequency of the audio content in the input signal, are shown for two exemplary speakers (e.g., Sample 1 and Sample 2) operating while rocking of a sound-generating element thereof is occurring. As shown in FIG. 7, for the first example speaker (e.g., Sample 1), the output current, Iout, includes a third order peak 702 (e.g., corresponding to the peak 406 or the peak 408 of FIG. 4) that is adjacent (e.g., in frequency space) to a corresponding dip 704 in the output current. For the second example speaker (e.g., Sample 2), the output current, Iout, includes a third order peak 708 (e.g., corresponding to the peak 406 or the peak 408 of FIG. 4) that is adjacent (e.g., in frequency space) to a corresponding dip 710 in the output current. An amount of rocking of the sound-generating element of the speakers may be proportional to the peak-to-dip ratio of the third order IMD peak(s) when an ultrasonic tone and one or more audible tones are concurrently output by a speaker. For example, in one or more implementations, the amount of rocking of the sound-generating element 215 may be aₘₐₓ=gain*A2, where gain is an experimentally determined gain factor, and A2 is the peak-to-dip amplitude of the third order IMD peak (e.g., peak-to-dip amplitude 700 or peak-to-dip amplitude 706 of FIG. 7).

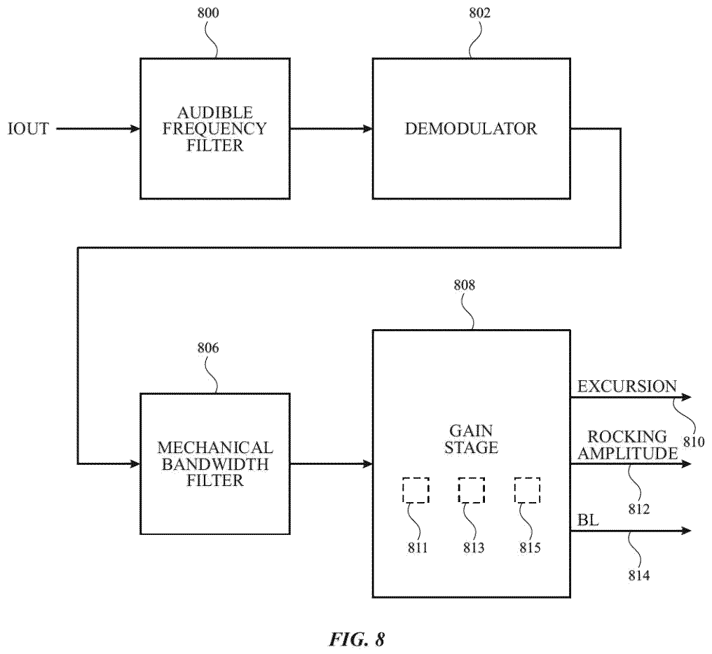

FIG. 8 illustrates an example architecture for monitoring speaker characteristics, such as the excursion, rocking amplitude, and/or force factor (BL) of a speaker, such as the speaker 114. For example, control circuitry (e.g., speaker circuitry 222 and/or device circuitry 224) for a speaker and/or an electronic device may include an audible frequency filter 800, a demodulator 802, a mechanical bandwidth filter 806, and a gain stage 808 in one or more implementations. For example, as shown in FIG. 8, the output current, Iout, from the voice coil 203 of a speaker 114 (e.g., a frequency transform of the output current, Iout, in frequency space) may be provided to an audible frequency filter 800. The audible frequency filter 800 may filter out variations in the output current, Iout, that correspond to audio content for the known audio output 310 in the human audible frequency range (e.g., based on the known variations corresponding to the audio content in the input current, Iin). The audible frequency filter 800 may also filter out higher order (e.g., fourth order or greater) content from the output current, Iout. In this way, a filtered output of the audible frequency filter 800 may preserve only portions of the frequency content in the output current, Iout, around the known ultrasonic frequency of the ultrasound output 312. The filtered output of the audible frequency filter 800 may be provided to a demodulator 802. For example, the demodulator 802 may implement a Hilbert transform or other demodulator to extract the IMD signal in the filtered output from a carrier signal (e.g., corresponding to the ultrasonic signal used to generate the ultrasound output 312).

As shown, a demodulated output from the demodulator 802 may be provided to a mechanical bandwidth filter 806. For example, the mechanical bandwidth filter 806 may be implemented as a low pass filter to filter out portions of the demodulated signal that are outside a mechanical bandwidth for the speaker (e.g., a bandwidth within which significant excursions of the sound-generating element 215 occur). For example, the mechanical bandwidth may be a bandwidth below three or four times the frequency (e.g., f₀) of the audio output 310 (e.g., a bandwidth below 1500 Hz for an audible frequency tone of five hundred Hz).

As shown, the filtered output from the mechanical bandwidth filter 806 may be provided to a gain stage 808. For example, the gain stage 808 may apply one or more gain factors to the filtered output of the mechanical bandwidth filter 806, to convert the signal amplitudes and/or peak-to-dip amplitudes in the filtered output of the mechanical bandwidth filter 806, to an excursion 810 (e.g., xₘₐₓ), a rocking amplitude 812 (e.g., aₘₐₓ), and/or a force factor (BL).

In one or more implementations, the gain stage 808 may apply the same gain (e.g., a gain factor 811) to multiple peaks in the output current, Iout, (e.g., multiple peaks in the filtered output of the mechanical bandwidth filter 806) to determine the excursion 810, the rocking amplitude 812, and/or the force factor 814. In one or more other implementations, the gain stage 808 may apply multiple different gains to multiple different peaks in the output current, Iout, (e.g., multiple peaks of different order in the filtered output of the mechanical bandwidth filter 806) to determine the excursion 810, the rocking amplitude 812, and/or the force factor 814. For example, the gain stage 808 may apply a gain factor 811 to the amplitude(s) of one or more second order IMD peaks to determine the excursion 810, may apply a gain factor 813 to the amplitudes and/or peak-to-dip amplitudes of one or more third order IMD peaks to determine the rocking amplitude, and/or may apply a gain factor 815 to one or more other features of the output current, Iout, (e.g., one or more other features of the filtered output of the mechanical bandwidth filter 806), to determine the force factor 814. The gain factor 811, the gain factor 813, and/or the gain factor 815 may be (e.g., experimentally determined) gain factors that are specific to a particular transducer or a particular speaker.

In one or more implementations, the excursion 810, the rocking amplitude 812, and/or the force factor 814 output from the gain stage 808 may be provided to the speaker circuitry 222 and/or the device circuitry 224, as feedback for operating the speaker 114 (e.g., for modifying the input current, Iin, to the speaker 114, for speaker protection and/or non-linearity correction based on the excursion 810, the rocking amplitude 812, and/or the force factor 814).

In various examples described herein, IMD features in the output current from a speaker are used to measure, identify, and/or monitor speaker characteristics, such as the excursion 810, the rocking amplitude 812, and/or the force factor 814. In one or more implementations, IMD features, such as higher order IMD peaks (e.g., fourth order or higher than fourth order peaks) may also be used to detect an impact in a speaker, such as the speaker 114. For example, IMD features, such as the higher order IMD peaks, may be used to identify an impact between a movable component of the speaker (e.g., the sound-generating element 215 and/or the voice coil 203) and one or more fixed components of the speaker (e.g., the fixed magnet 302, the fixed magnet 304, a portion of the speaker housing 200, a portion of the housing 106 of the electronic device 100, and/or any other fixed structure of the speaker 114 or the electronic device 100).

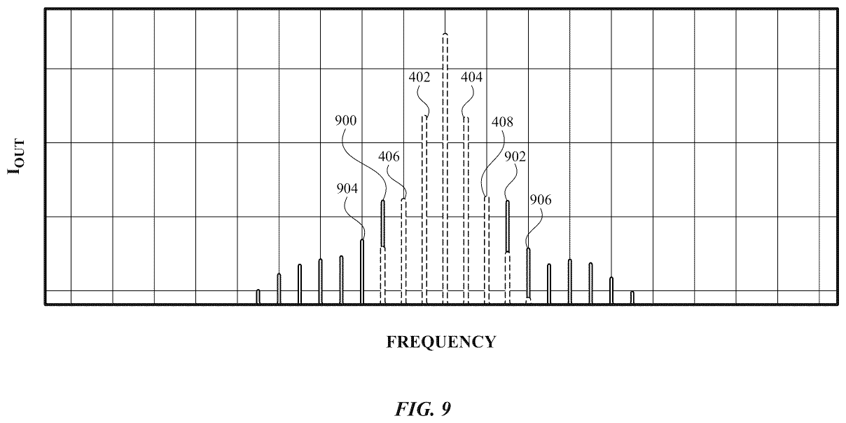

FIG. 9 illustrates an affect, of an impact within a speaker, on the IMD features in the output current of a speaker. For example, FIG. 9 may represent a (e.g., normalized) frequency transform (e.g., a Fourier transform, such as a Fast Fourier Transform (FFT)) of the current, Iout, in frequency space. In the example of FIG. 9, IMD peaks represented in dashed lines may represent the IMD features in the output current, Iout, in the absence of an impact within the speaker (e.g., including second order peaks, such as the peaks 402 and 404 of FIG. 4, and third order peaks, such as the peaks 406 and 408 of FIG. 4). As indicated by the peaks shown in solid lines in FIG. 9, when an impact occurs within the speaker, the higher order peaks (e.g., fourth order and higher than fourth order) may be affected in a way that is detectable (e.g., using the current meter 324 of FIG. 3). For example, as shown, the fourth order peaks, such as peaks 900 and 902 (e.g., on opposing sides, in frequency space, of the frequency of the ultrasound output 312) may increase in amplitude when an impact occurs, relative to the amplitude of the fourth order peaks in the absence of an impact within the speaker. The amplitudes of IMD peaks having an order higher than the fourth order (e.g., peaks 904 and 906, such as fifth order peaks, and/or additional peaks, such as sixth order peaks, and/or seventh order and higher peaks) may also increase in amplitude (e.g., to detectable levels) when an impact occurs in the speaker. For example, because an impact within the speaker may be similar to an external impulse input to speaker, the energy of the impact may spread into the higher order IMD peaks. In one or more implementations, an impact in a speaker may be detected by detecting a change in the amplitude of an IMD peak of fourth order or higher. In one or more implementations, an impact in a speaker may be detected by detecting an amplitude of an IMD peak of fourth order or higher that exceeds a threshold amplitude.

In one or more implementations, an impact within a speaker may also cause one or more asymmetries, in frequency space, of the IMD features. For example, in the presence of an impact, the peak 900 (e.g., a fourth order peak on one side of the carrier frequency) may have an amplitude that is higher than the amplitude of the peak 902 (e.g., the fourth order peak on the other side of the carrier frequency), and/or the peak 904 (e.g., a fifth order peak on one side of the carrier frequency) may have an amplitude that is higher than the amplitude of the peak 906 (e.g., the fifth order peak on the other side of the carrier frequency). In one or more implementations, an impact in a speaker may be detected by detecting an asymmetry in the amplitudes of two or more IMD peaks of fourth order or higher.

In one or more implementations, impact detection using IMD features may be performed (e.g., during manufacturing and/or assembly of a speaker and/or an electronic device) to determine the available excursion range of a speaker. For example, due to manufacturing and/or component tolerances, the level of excursion and/or the available clearances for each speaker may be different. In one or more implementations, the higher order IMD peaks may be used to non-invasively identify a maximum excursion range for each speaker (e.g., to identify an excursion range in which the speaker can be operated without risk of impact). For example, while the audio output 310 and the ultrasound output 312 are being generated by the speaker 114, the voltage (e.g., corresponding to the amplitude of the audio output and/or the ultrasound output) may be elevated while monitoring the output current, Iout, at different values of input voltages. While increasing the voltage, detection of an impact based on the higher (e.g., fourth or higher) order IMD peaks (e.g., based on a change, an amplitude, and/or an asymmetry) in the current signal around the carrier frequency may reveal the voltage level at which an impact will occur. In one or more implementations, this voltage (e.g., modified to include a safety tolerance amount) may be set as the voltage limit for speaker operations to prevent impacts from occurring during use of the speaker (e.g., by a user of the electronic device 100). In one or more other implementations, impact detection may also, or alternatively, be performed during use, by a user of an electronic device having a speaker.

In accordance with some aspects of the subject disclosure, a method may be provided that includes operating a speaker to output at least a first tone in a human audible frequency range and a second tone configured as a human inaudible tone; and detecting an impact within the speaker based on an intermodulation distortion generated by the at least the first tone and the second tone. In one or more implementations, the method may also include setting a maximum operating range (e.g., a maximum excursion and/or or maximum operating voltage) based on the detected impact. For example, setting the maximum operating range may include detecting a range limit for the operating range based on a value (e.g., a voltage or an excursion) of the operating range when the impact is detected using the intermodulation distortion. In one or more implementations, detecting the impact within the speaker based on the intermodulation distortion may include detecting a change, an amplitude, and/or an asymmetry of one or more IMD peaks having an order that is fourth order or higher than fourth order.

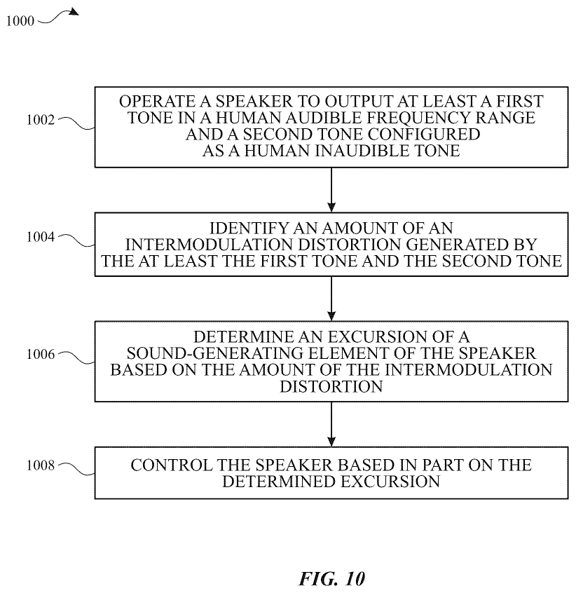

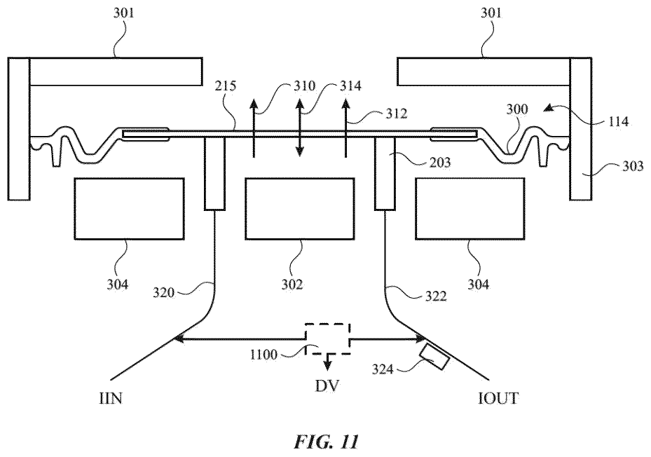

FIG. 10 illustrates a flow diagram of an example process for speaker monitoring, in accordance with one or more implementations. For explanatory purposes, the process 1000 is primarily described herein with reference to the electronic device 100 and the speaker 114 of FIGS. 1 and 2. However, the process 1000 is not limited to the electronic device 100 and the speaker 114 of FIGS. 1 and 2, and one or more blocks (or operations) of the process 1000 may be performed by one or more other components and other suitable devices. Further for explanatory purposes, the blocks of the process 1000 are described herein as occurring in serial, or linearly. However, multiple blocks of the process 1000 may occur in parallel. In addition, the blocks of the process 1000 need not be performed in the order shown and/or one or more blocks of the process 1000 need not be performed and/or can be replaced by other operations.

In the example of FIG. 10, at block 1002, a speaker (e.g., speaker 114) may be operated to output at least a first tone (e.g., audio output 310) in a human audible frequency range (e.g., between 20 Hz and 20 kHz) and a second tone configured as a human inaudible tone. For example, the second tone may include a tone in a human inaudible frequency range (e.g., the ultrasound output 312 in an ultrasonic frequency range, such as a frequency of greater than 20 kHz, such as a frequency at or near 21 kHz). As another example, the second tone may include a tone in the human audible frequency range and having an amplitude that is below a human audibility threshold amplitude. In one or more implementations, the human audibility threshold amplitude may vary based on the amplitude of at least the first tone. For example, the human audibility threshold may be set to twenty microPascals or zero decibels (dB), or may be raised to a threshold that is higher than zero dB and significantly less than (e.g., by a predetermined amount, such as half, five times less than, ten times less than, one hundred times less than, or more than one hundred times less than) the amplitude of the first tone. In this way, in one or more implementations, a second tone can be output in a human audible frequency range while still being configured to be a human inaudible tone that causes IMD at one or more known frequencies. In one example, the at least the first tone may be a single tone in the human audible frequency range. In another example, the at least the first tone may include a sweep of tones in the human audible frequency range. In yet another example, the at least the first tone may include a tone of a multiple tones corresponding to media content being output by the speaker (e.g., the tone may be one of many tones being generated during output of music or other media content by the speaker).

At block 1004, an amount of an intermodulation distortion (IMD) generated by the at least the first tone and the second tone may be determined (e.g., by speaker circuitry 222 or device circuitry 224). For example, the amount of the intermodulation distortion may include an amplitude of a first intermodulation distortion peak (e.g., peak 402 or peak 404) generated by the intermodulation distortion in a current passing through the speaker (e.g., and resulting in an output current, Iout, from the speaker).

At block 1006, an excursion (e.g., as indicated by arrows 314, such as an amplitude of the excursion) of a sound-generating element (e.g., sound-generating element 215, such as a diaphragm or stiffener) of the speaker may be determined (e.g., by speaker circuitry 222 or device circuitry 224) based on the amount of the intermodulation distortion. In one or more implementations, determining the excursion of the sound-generating element of the speaker based on the amount of the intermodulation distortion may include obtaining an amplitude (e.g., an amplitude, A, as shown in FIG. 4) of an intermodulation distortion peak (e.g., peak 402 or peak 404) in an output current (e.g., Iout) from the speaker, and applying a speaker-specific gain factor (e.g., gain factor 811) for the speaker to the amplitude of the intermodulation distortion peak in the output current to obtain the excursion (e.g., excursion 810).

At block 1008, the speaker may be controlled (e.g., by speaker circuitry 222 or device circuitry 224) based in part on the determined excursion. For example, controlling the speaker may include modifying an output of the speaker (e.g., by modifying an input current, Iin, being provided to the speaker) to prevent the excursion from exceeding a predetermined maximum excursion for speaker protection (e.g., to prevent the sound-generating element or any other movable portion of the speaker from impacting a fixed structure of the speaker or a device in which the speaker is implemented). As another example, the controlling may include adjusting audio content being output by the speaker to correct for a speaker non-linearity (e.g., to reduce rocking of the sound-generating element).

In one or more implementations, the process 1000 may also include identifying a peak-to-dip amplitude (e.g., peak-to-dip amplitude 700 or peak-to-dip amplitude 706) of a second intermodulation distortion peak (e.g., peak 406, peak 408, peak 702, or peak 708) generated by the intermodulation distortion in the current passing through the speaker. For example, the first intermodulation distortion peak may be a second order peak (e.g., a second order IMD peak, such as a peak located at or near the frequency of the second tone plus or minus the frequency of the first tone), and the second intermodulation distortion peak may be a third order peak (e.g., a third order IMD peak, such as a peak located at or near a frequency of the second tone plus or minus twice the frequency of the first tone). The process 1000 may also include determining a rocking characteristic (e.g., a rocking amplitude, such as an amplitude, aₘₐₓ, of a motion of one or more corners 500 or edges of the sound-generating element 215 in addition to an overall excursion of the sound-generating element such as a motion of a center 501 of the sound-generating component) of the sound-generating element based on the peak-to-dip amplitude. The process 1000 may also include (e.g., as part of the controlling of block 1008), controlling the speaker based on the excursion and the rocking characteristic. For example, controlling the speaker based on the rocking characteristic may include modifying one or more frequencies of the audio output to reduce or eliminate a rocking of the sound-generating component.

In one or more implementations, the process 1000 may also include determining a force factor (e.g., BL) of the speaker based on the intermodulation distortion generated by the at least the first tone and the second tone, and controlling (e.g., as part of the controlling of block 1008) the speaker based on the excursion, the rocking characteristic, and the force factor. In one or more implementations, the process 1000 may also include detecting an impact of a component (e.g., the sound-generating element 215 and/or the voice coil 203) of the speaker based on the amount of the intermodulation distortion. For example, detecting the impact of the component of the speaker based on the amount of the intermodulation distortion may include detecting the impact of a component of the speaker based on an amplitude (e.g., and/or a change in the amplitude) of a peak (e.g., peak 900, peak 902, peak 904, and/or peak 906), having an order that is fourth order or higher than fourth order, in the intermodulation distortion.

In various examples discussed herein, the excursion, rocking, and/or force factor of a speaker, such as the speaker 114, are determined using one or more amplitudes of one or more intermodulation distortion (IMD) peaks in an output current of the speaker, the IMD peaks resulting from outputting a human audible tone and a human inaudible tone (e.g., an ultrasound tone) with the speaker. It is also appreciated that the excursion, rocking, and/or force factor of a speaker, such as the speaker 114, may also, or alternatively, be determined using one or more amplitudes of one or more peaks in the output current of the speaker resulting from outputting multiple tones in the same frequency range (e.g., multiple tones in a human audible range or multiple tones in a human inaudible range). For example, the amplitude(s) and/or phases of one or more peak(s), such interference peaks (e.g., at one or more beat frequencies) resulting from outputting two ultrasound tones may be used to determine the excursion, rocking, and/or force factor of a speaker.

In this example in which two ultrasonic tones are used, the amplitudes and frequencies of the two ultrasonic tones may be selected such that the magnitude of a resulting difference tone (e.g., an tone at a beat frequency corresponding to the difference between, and/or the sum of, the two frequencies of the two ultrasonic tones) is greater than a noise floor of a sensing system, and/or the frequency of the resulting difference tone is greater than a total harmonic distortion (THD) frequency of the speaker (e.g., the transducer of the speaker). For example, an ultrasonic carrier tone may be output at a first ultrasonic frequency, an ultrasonic modulator tone may be output at a second ultrasonic frequency, and the difference tone (e.g., at a difference frequency corresponding to the difference between the first ultrasonic frequency and the second ultrasonic frequency) may also be an ultrasonic tone. In one or more implementations, the excursion of a speaker, such as the speaker 114, may also, or alternatively, be determined using an amplitude of a peak in the output current resulting from a single ultrasonic tone (e.g., without intermodulation distortion). For example, for an ultrasonic output tone having a magnitude that is greater than the noise floor of the sensing system, and a frequency greater than the THD frequency of the speaker, the amplitude and/or phase of a peak in the output current and/or output voltage at that same frequency may include sufficient information to determine the excursion of the speaker (e.g., by applying a gain factor to the amplitude of the current at that frequency).

It is also appreciated that, in implementations in which a human inaudible tone (e.g., alone or together with a human audible tone) is output by the speaker 114 (e.g. as in the example of FIG. 3), the excursion, rocking, and/or force factor of the speaker 114 may be determined using electrical characteristics other than, and/or in addition to, the output current, Iout, of the speaker 114 and/or speaker circuit (e.g., including the voice coil 203, the conductive element 320, and/or the conductive element 322) thereof.

For example, FIG. 11 illustrates an example implementation in which both the current, through the speaker circuit (e.g., the output current, Iout) and a voltage, DV, across the speaker circuit are measured during operation of the speaker 114 (e.g., speaker operation to output the ultrasound output 312 and/or the audio output 310, or to generate two ultrasound outputs 312 at two different ultrasound frequencies). For example, the voltage, DV, may be a voltage difference between the conductive element 320 and the conductive element 322, and may be measured using a voltage sensor 1100 coupled between the conductive element 320 and the conductive element 322. In one or more implementations, a phase of the current, Iout (e.g., at the frequency of the ultrasound output 312, at an ultrasonic difference frequency resulting from generating two ultrasonic outputs at two different ultrasonic frequencies, and/or at one or more IMD frequencies resulting from the audio output 310 and the ultrasound output 312) and a phase of the voltage, DV (e.g., at the frequency of the ultrasound output 312, at the ultrasonic difference frequency resulting from generating two ultrasonic outputs at two different ultrasonic frequencies, and/or at one or more IMD frequencies resulting from the audio output 310 and the ultrasound output 312), may be determined. In one or more implementations, a transform, such as a Hilbert transform, may be applied to the output current, Iout, and to the voltage, DV. For example, the Hilbert transform may output the time varying amplitude and/or phase of each signal (e.g., the output current, Iout, and the voltage, DV) to which the transform is applied. In one or more other implementations, the phase of the output current and/or the phase of the voltage may be determined by determining a difference between a time at which a feature (e.g., a difference frequency peak or an IMD peak) appears in the output current relative to a known time of a corresponding feature in the input tone(s) in the input current, Iin.

In one or more implementations, the phase of the current, Iout (e.g., at the frequency of the ultrasound output 312, at the ultrasonic difference frequency resulting from generating two ultrasonic outputs at two different ultrasonic frequencies, and/or at one or more IMD frequencies resulting from the audio output 310 and the ultrasound output 312) and the phase of the voltage, DV (e.g., at the frequency of the ultrasound output 312, at the ultrasonic difference frequency resulting from generating two ultrasonic outputs at two different ultrasonic frequencies, and/or at one or more IMD frequencies resulting from the audio output 310 and the ultrasound output 312), may be used to determine the excursion and/or the rocking of the sound-generating element 215 of the speaker 114.

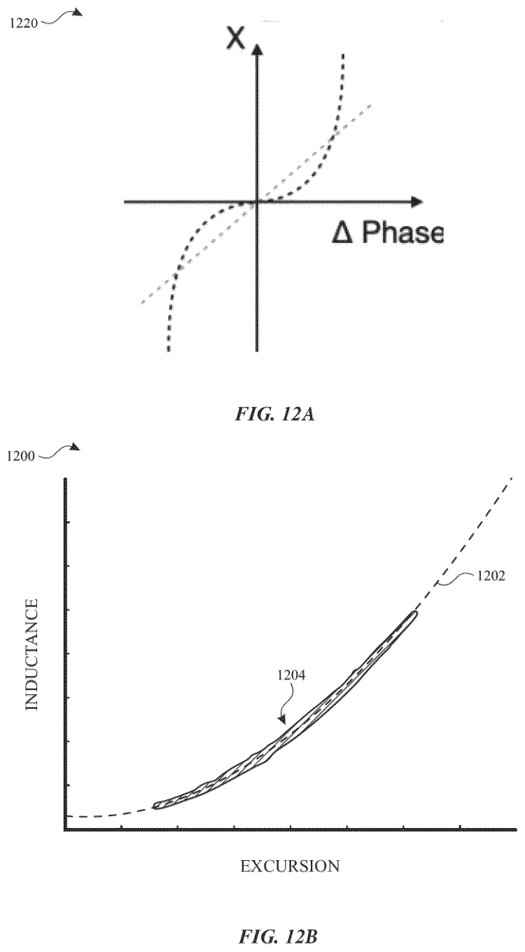

For example, a peak in the output current, Iout (e.g., an IMD peak resulting from outputting the ultrasound output 312 and/or the audio output 310, or an interference peak resulting from outputting two ultrasound outputs 312 at two different ultrasound frequencies), may occur at a slightly different time from a time at which a peak (e.g., an IMD peak resulting from outputting the ultrasound output 312 and/or the audio output 310, or an interference peak resulting from outputting two ultrasound outputs 312 at two different ultrasound frequencies) in the voltage, DV occurs, even though both the current and voltage peaks result from the same output of the speaker at the same time. This timing difference may correspond to the phase difference between the current and the voltage, and may be due to one or more time-variable non-linearities in the speaker. In one or more implementations, the phase difference (e.g., at the frequency of the ultrasound output 312, at the ultrasonic difference frequency resulting from generating two ultrasonic outputs at two different ultrasonic frequencies, and/or at one or more IMD frequencies resulting from the audio output 310 and the ultrasound output 312) between the phase of the current, Iout, and the phase of the voltage, DV, may be used (e.g., by applying a gain factor, such as an experimentally determined gain factor, to the phase difference) to obtain the excursion of the sound-generating element 215. For example, the current, Iout, and the voltage, DV, may be measured while two ultrasound outputs 312 are generated; a band-pass filter (e.g., around the difference frequency between the ultrasonic frequencies of the two ultrasound outputs) may be applied to the measured current, Iout, and voltage, DV; the phases of the band-pass filtered current, Iout, and voltage, DV, may be determined; a difference in the phases of the current, Iout, and the voltage, DV, may be determined; and the excursion of the speaker may be obtained using the determined phase difference and a phase difference-excursion map (e.g., a phase difference-excursion map 1220, as shown in FIG. 12A as one example of a mapping between phase difference and excursion). For example, the phase-excursion map 1220 (e.g., in which “X” represents the excursion, and “A Phase” represents the measured phase difference between current and voltage) may have been previously determined experimentally by measuring the phases differences while separately measuring the excursions in a different way (e.g., using laser-measured positions of the sound-generating element 215).

In one or more other implementations, further processing of the current, Iout, the voltage, DV, the phase of the current, Iout, and/or the phase of the voltage, DV, may be performed to determine the excursion and/or the rocking of the sound-generating element 215. For example, the current, Iout, the voltage, DV, the phase of the current, Iout, and the phase of the voltage, DV, may be used to determine (e.g., at various times) an inductance and/or a resistance of the speaker circuit of the speaker 114, and the excursion and/or rocking may be determined using the inductance and/or the resistance. For example, FIG. 12B illustrates an inductance-excursion map 1200 that may be used to obtain an excursion value that corresponds to a measured inductance value. In the example of FIG. 12B, the inductance-excursion map 1200 includes a pre-determined curve 1202 having an excursion value for each inductance value. For example, the pre-determined curve 1202 may be a curve that has been fitted to a set 1204 of measured inductances of the speaker 114 at a set of corresponding known excursions (e.g., measured in a laboratory or factory using an external sensor, such as a laser sensor). When the speaker 114 is in use, in order to determine the excursion of the speaker 114 (e.g., the sound-generating element 215 of the speaker 114) at any time, a human inaudible tone may be added to the output of the speaker 114, the inductance at a frequency that is based on the human inaudible tone (e.g., the frequency of the human inaudible tone itself, and/or one or more IMD frequencies resulting from the human inaudible tone and one or more human audible tones in the output of the speaker 114) may be determined, and the excursion corresponding to that determined inductance can be extracted from the inductance-excursion map 1200.

However, the inductance and the resistance of the speaker circuit are non-trivial electrical characteristics determine (e.g., relative to directly measurable electrical characteristics like the current and/or the voltage). In one or more implementations, the current, Iout, the voltage, DV, the phase of the current, Iout, and the phase of the voltage, DV, may be used to determine (e.g., at various times) the inductance and the resistance of the speaker circuit of the speaker 114 by determining a complex impedance using the current, Iout, the voltage, DV, the phase of the current, Iout, and the phase of the voltage, DV. For example, a transform, such as the Hilbert transform, may be used to obtain the complex voltage and complex current from the voltage, DV, and the current, Iout. The complex impedance may then be determined by, for example, dividing the complex voltage by the complex current. As another example, the complex impedance may be determined by dividing the measured voltage by the measured current, and applying the transform to the result of the division. As another, the voltage may be expressed as a complex number using a phasor representation of the voltage that is based on the voltage, DV, and the phase of the voltage, DV, and the current may be expressed as a complex number using a phasor representation of the current that is based on the current, Iout, and the phase of the current, Iout (e.g., wherein the phase of the current or the phase of the voltage is measured relative to the phase of the other of the current or the voltage). Once the complex impedance has been determined, the resistance of the speaker circuit may be obtained by extracting the real part of the complex impedance, and the inductance of the speaker circuit may be obtained by extracting the imaginary part of the complex impedance (e.g., the part of the complex impedance that is multiplied by the square root of negative 1, or i).

In one or more implementations, the relationship between excursion and inductance may change over time, such as due to changes in the temperature of the magnets 302 and/or 304 of the speaker 114 during operation of the speaker 114. For example, changes in magnet temperature can change how magnetic fields are generated within and around the voice coil when current is passed through the voice coil, such as due to temperature-induced changes in the magnetic fields of the magnets themselves, which interact with magnetic fields generated by the changing currents in the voice coil. In one or more implementations, the resistance of the speaker circuit (e.g., obtained from the real part of the complex impedance) may be used, along with a thermal model of the speaker, to modify the inductance-excursion map 1200 to account for changes in magnet temperature. For example, the resistance determined at a particular time during operation of the speaker 114 may be used to extract, from the thermal model of the speaker, a modification to be applied to the inductance-excursion map 1200 (e.g., before the inductance-excursion map 1200 is used to determine the current excursion of the sound-generating element 215).

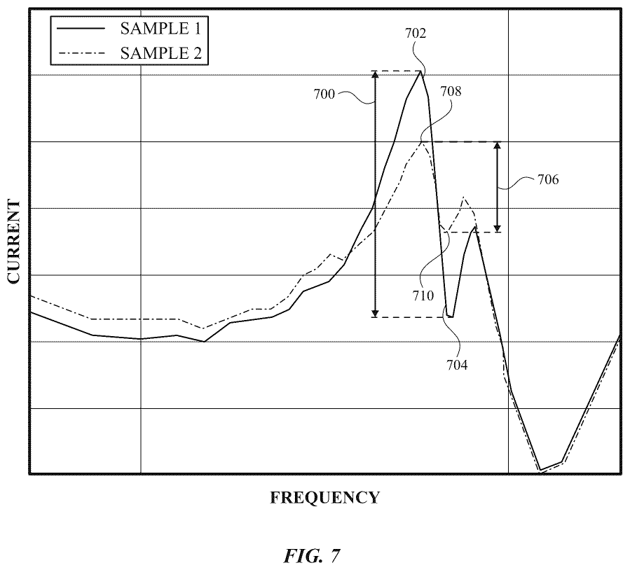

It is also appreciated that the inductance of the speaker circuit of the speaker 114 can also be used to determine and/or pre-compensate for rocking of the sound-generating element 215 (e.g., rocking as described herein in connection with FIGS. 5 and 6). For example, an inductance spectrum may be obtained from the change in the inductance (e.g., determined based on the complex impedance as discussed above) over time (e.g., by applying a transform, such as a Fourier transform, or Fast Fourier Transform (FFT), to a series of inductance values determined over time during operation of the speaker 114). The rocking motion of the sound-generating element 215 may then be determined based on the inductance spectrum. For example, the rocking motion may be determined based on one or more amplitudes of one or more peaks in the inductance spectrum. For example, the amplitude of a peak in the inductance spectrum at a frequency, in the inductance spectrum, that is a factor (e.g., half) of a frequency of the human audible tone (e.g., audio output 210) that is output by the speaker 114 may be a proxy for the amount of rocking that is occurring in the sound-generating element 215.

In one or more implementations, an inductance spectrum-rocking map may be generated by measuring, for a set of known (e.g., concurrently measured using an external sensor, such as a laser sensor) rocking motions and known human audible input tones, a set of amplitudes of the peak at the frequency, in the inductance spectrum, that is the factor (e.g., half) of the frequency of the human audible tone. Once this inductance spectrum-rocking map has been determined, during operation of the speaker 114 (e.g., by an end user), an audio signal to be output by the speaker 114 may be used to determine an estimated inductance that will result from operating the speaker 114 using the audio signal. The estimated inductance and the previously determined (e.g. pre-determined prior to end user operation of the speaker) inductance spectrum-rocking map may then be used to predict an expected rocking of the sound-generating element 215 that would occur if the speaker were to be operated using the audio signal. The audio signal may then be modified to pre-compensate for the expected rocking, so that, when the modified audio signal is output by the speaker 114, audio content of the audio signal is output without causing what was the expected rocking of the speaker 114. For example, portions (e.g., in frequency) of the audio signal that generate peaks in the inductance spectrum that have been previously determined to cause rocking in the speaker 114, can be suppressed in, or removed from, the audio signal prior to output of the audio signal by the speaker 114.

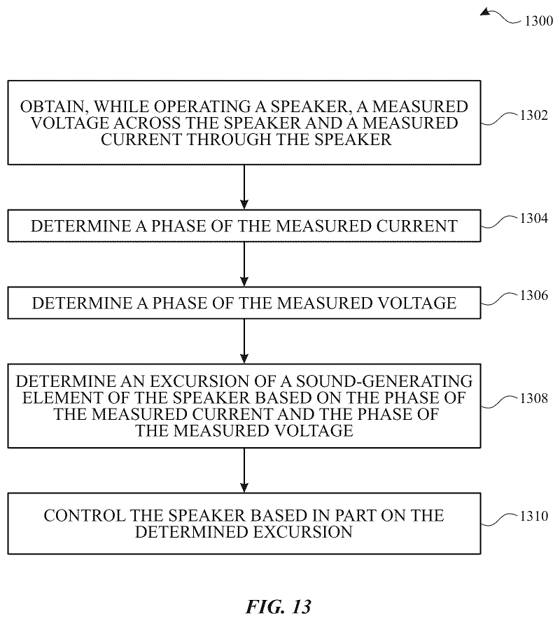

FIG. 13 illustrates a flow diagram of another example process for speaker monitoring, in accordance with one or more implementations. For explanatory purposes, the process 1300 is primarily described herein with reference to the electronic device 100 and the speaker 114 of FIGS. 1 and 2. However, the process 1300 is not limited to the electronic device 100 and the speaker 114 of FIGS. 1 and 2, and one or more blocks (or operations) of the process 1300 may be performed by one or more other components and other suitable devices. Further for explanatory purposes, the blocks of the process 1300 are described herein as occurring in serial, or linearly. However, multiple blocks of the process 1300 may occur in parallel. In addition, the blocks of the process 1300 need not be performed in the order shown and/or one or more blocks of the process 1300 need not be performed and/or can be replaced by other operations.

In the example of FIG. 13, at block 1302, a measured voltage (e.g., DV) across a speaker (e.g., speaker 114) and a measured current (e.g., Iout) through the speaker (e.g., through a voice coil of the speaker) may be obtained (e.g., by an electronic device including the speaker, such as the electronic device 100) while operating the speaker (e.g., operating the speaker to output audio content, such as media content, according to an audio signal). For example, operating the speaker may include outputting a tone with the speaker. For example, the tone may include a human inaudible tone, such as an ultrasonic tone or another human inaudible tone as described herein. In one or more implementations, operating the speaker may also include outputting at least one human-audible tone (e.g., a tone having a frequency within a human-audible frequency range) with the speaker. For example, the human-audible tone may be a single tone or a tone of a set of tones for generating, in combination with the ultrasonic tone, an IMD effect. As another example, the human-audible tone may include a tone of multiple tones corresponding to media content output by the speaker.

At block 1304, a phase of the measured current may be determined. For example, obtaining the phase of the measured current may include applying a (e.g., Hilbert) transformation to the measured current. As another example, determining the phase of the measured current may include determining one or more times of one or more features (e.g., peaks) in the measured current, relative to one or more respective times of one or more respective features in an input current (e.g., Iin) used for operating the speaker.

At block 1306, a phase of the measured voltage may be obtained. For example, obtaining the phase of the measured voltage may include applying a (e.g., Hilbert) transformation to the measured voltage. As another example, determining the phase of the measured voltage may include determining one or more times of one or more features (e.g., peaks) in the measured voltage, relative to one or more respective times of one or more respective features in the input current (e.g., Iin) used for operating the speaker and/or relative to one or more respective features in the measured current.

At block 1308, an excursion of a sound-generating element (e.g., sound-generating element 215) of the speaker may be determined based on the phase of the measured current and the phase of the measured voltage. For example, determining the excursion of the sound-generating element of the speaker based on the phase of the measured current and the phase of the measured voltage may include determining the excursion of the sound-generating element of the speaker based on a difference (e.g., phase difference) between the phase of the measured current and the phase of the measured voltage.

As another example, determining the excursion of the sound-generating element of the speaker based on the phase of the measured current and the phase of the measured voltage may include, while outputting the human audible tone and the ultrasonic tone: determining a complex impedance of a speaker circuit (e.g., a circuit including the voice coil 203, the conductive element 320 and/or the conductive element 322) of the speaker based on the phase of the measured current and the phase of the measured voltage; and determining the excursion based on the complex impedance.

For example, determining the excursion based on the complex impedance may include obtaining an inductance of the speaker circuit from a first part (e.g., an imaginary part) of the complex impedance; and determining the excursion based on the inductance. For example, determining the excursion based on the inductance may include obtaining the excursion from a pre-stored inductance-excursion map (e.g., inductance-excursion map 1200) using the inductance.

In one or more implementations, determining the excursion based on the inductance may also include modifying, prior to obtaining the excursion from the pre-stored inductance-excursion map, the pre-stored inductance-excursion map based on a thermal model of the speaker circuit and a resistance determined based on a second part of the complex impedance.

At block 1310, the speaker may be controlled (e.g., by the electronic device) based in part on the determined excursion. As examples, controlling the speaker may include modifying an output of the speaker to prevent the excursion from exceeding a predetermined maximum excursion for speaker protection, and/or adjusting audio content being output by the speaker to correct for a speaker non-linearity.

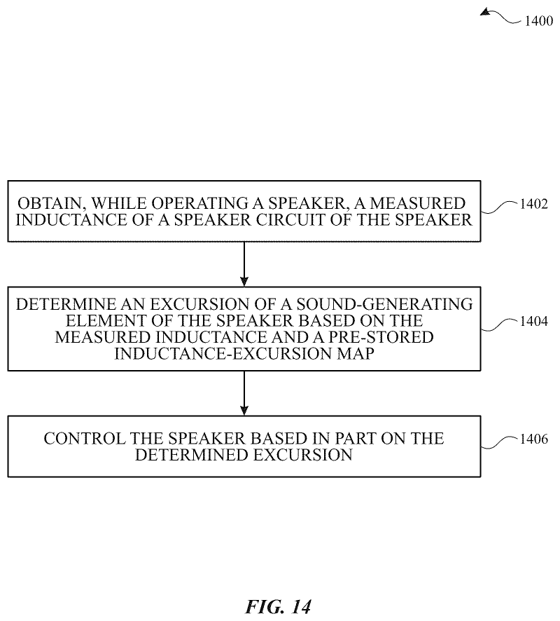

FIG. 14 illustrates a flow diagram of another example process for speaker monitoring, in accordance with one or more implementations. For explanatory purposes, the process 1300 is primarily described herein with reference to the electronic device 100 and the speaker 114 of FIGS. 1 and 2. However, the process 1400 is not limited to the electronic device 100 and the speaker 114 of FIGS. 1 and 2, and one or more blocks (or operations) of the process 1400 may be performed by one or more other components and other suitable devices. Further for explanatory purposes, the blocks of the process 1400 are described herein as occurring in serial, or linearly. However, multiple blocks of the process 1400 may occur in parallel. In addition, the blocks of the process 1400 need not be performed in the order shown and/or one or more blocks of the process 1400 need not be performed and/or can be replaced by other operations.

In the example of FIG. 14, at block 1402, while operating a speaker (e.g., speaker 114), a measured inductance of a speaker circuit (e.g., a circuit including the voice coil 203, the conductive element 320 and/or the conductive element 322) of the speaker may be obtained (e.g., by an electronic device, such as electronic device 100, that includes the speaker).

At block 1404, an excursion of a sound-generating element (e.g., sound-generating element 215) of the speaker may be determined based on the measured inductance and a pre-stored inductance-excursion map (e.g., inductance-excursion map 1200). For example, determining the excursion of the sound-generating element based on the measured inductance and the pre-stored inductance-excursion map may include determining an impedance of the speaker circuit based on a current through the speaker circuit and a voltage across the speaker circuit; and determining the inductance based on a first part (e.g., an imaginary part) of the impedance. Determining the excursion of the sound-generating element based on the measured inductance and the pre-stored inductance-excursion map further may include determining a resistance based on a second part (e.g., a real part) of the impedance; and modifying the pre-stored inductance-excursion based on the resistance and a thermal model of the speaker.

In one or more implementations, determining the impedance of the speaker circuit based on the current through the speaker circuit and the voltage across the speaker circuit may include determining the impedance of the speaker circuit based on a phase of the current through the speaker circuit and a phase of the voltage across the speaker circuit.

At block 1406, the speaker may be controlled (e.g., by the electronic device) based in part on the determined excursion. As examples, controlling the speaker may include modifying an output of the speaker to prevent the excursion from exceeding a predetermined maximum excursion for speaker protection, and/or adjusting audio content being output by the speaker to correct for a speaker non-linearity.

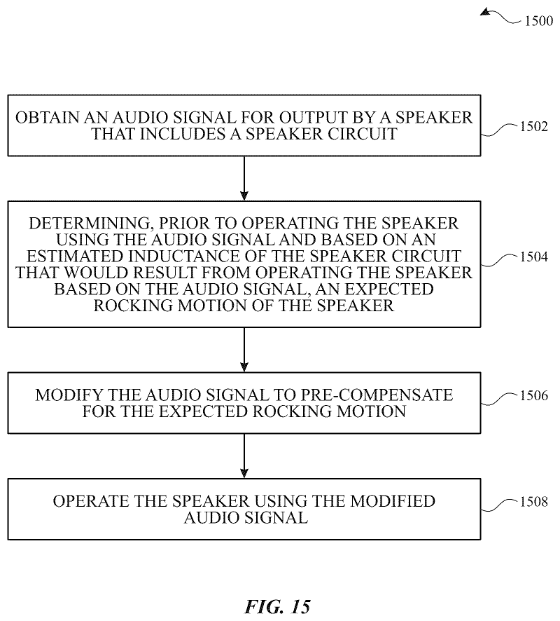

FIG. 15 illustrates a flow diagram of an example process for speaker protection, in accordance with one or more implementations. For explanatory purposes, the process 1500 is primarily described herein with reference to the electronic device 100 and the speaker 114 of FIGS. 1 and 2. However, the process 1500 is not limited to the electronic device 100 and the speaker 114 of FIGS. 1 and 2, and one or more blocks (or operations) of the process 1500 may be performed by one or more other components and other suitable devices. Further for explanatory purposes, the blocks of the process 1500 are described herein as occurring in serial, or linearly. However, multiple blocks of the process 1500 may occur in parallel. In addition, the blocks of the process 1500 need not be performed in the order shown and/or one or more blocks of the process 1500 need not be performed and/or can be replaced by other operations.

In the example of FIG. 15, at block 1502, an audio signal for output by a speaker (e.g., speaker 114) that includes a speaker circuit (e.g., a circuit including the voice coil 203, the conductive element 320 and/or the conductive element 322) may be obtained (e.g., by speaker circuitry 222 and/or device circuitry 224). The audio signal may include media content for output by the speaker. For example, the audio signal may, when output by the speaker, cause the speaker to generate an audio output (e.g., audio output 210) that includes content, such as media content.

At block 1504, prior to operating the speaker using the audio signal and based on an estimated inductance of the speaker circuit that would result from operating the speaker based on the audio signal, an expected rocking motion of the speaker (e.g., of a sound-generating element of the speaker, such as sound-generating element 215) may be determined. As examples, the expected rocking motion may be an expected angle of rotation of the sound-generating element 215, or an expected amount of displacement of an edge or a corner of the sound-generating element 215 relative to a center or another edge or corner of the sound-generating element 215. Determining the expected rocking motion of speaker based on the estimated inductance may include determining the estimated inductance in part by determining an estimated phase of a voltage across the speaker circuit and an estimated phase of a current through the speaker circuit. In one or more implementations, determining the expected rocking motion of speaker based on the estimated inductance may include estimating a time variation of the estimated inductance; obtaining an estimated inductance spectrum based on the time variation of the estimated inductance (e.g., by applying a transform, such as a Fourier transform to the estimated inductance), obtaining an amplitude of a peak in the estimated inductance spectrum; and determining the expected rocking based on the amplitude of the peak and a previously measured mapping between speaker rocking and inductance spectra.

At block 1506, the audio signal may be modified (e.g., by speaker circuitry 222 and/or device circuitry 224) to pre-compensate for the expected rocking motion. For example, the peak may be located at a frequency in the estimated inductance spectrum, and modifying the audio signal may include modifying (e.g., suppressing or removing) a portion (e.g., a frequency band) of the audio signal having a frequency that is a factor (e.g., half) of the frequency of the peak in the inductance spectrum.

At block 1508, the speaker may be operated (e.g., by speaker circuitry 222 and/or device circuitry 224) using the modified audio signal. For example, operating the speaker using the modified audio signal that has been modified to pre-compensate for the expected rocking motion may cause the speaker to output the content of the audio signal without causing the expected rocking motion of the speaker.

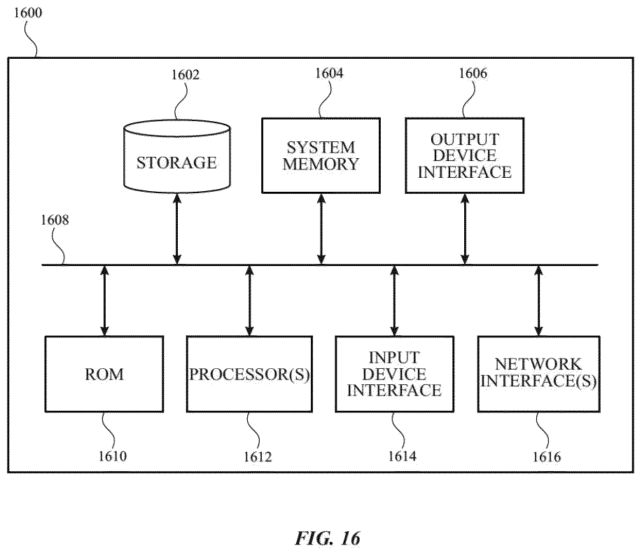

FIG. 16 illustrates an electronic system 1600 with which one or more implementations of the subject technology may be implemented. The electronic system 1600 can be, and/or can be a part of, one or more of the electronic device 100 shown in FIG. 1. The electronic system 1600 may include various types of computer readable media and interfaces for various other types of computer readable media. The electronic system 1600 includes a bus 1608, one or more processing unit(s) 1612, a system memory 1604 (and/or buffer), a ROM 1610, a permanent storage device 1602, an input device interface 1614, an output device interface 1606, and one or more network interfaces 1616, or subsets and variations thereof.

The bus 1608 collectively represents all system, peripheral, and chipset buses that communicatively connect the numerous internal devices of the electronic system 1600. In one or more implementations, the bus 1608 communicatively connects the one or more processing unit(s) 1612 with the ROM 1610, the system memory 1604, and the permanent storage device 1602. From these various memory units, the one or more processing unit(s) 1612 retrieves instructions to execute and data to process in order to execute the processes of the subject disclosure. The one or more processing unit(s) 1612 can be a single processor or a multi-core processor in different implementations.

The ROM 1610 stores static data and instructions that are needed by the one or more processing unit(s) 1612 and other modules of the electronic system 1600. The permanent storage device 1602, on the other hand, may be a read-and-write memory device. The permanent storage device 1602 may be a non-volatile memory unit that stores instructions and data even when the electronic system 1600 is off. In one or more implementations, a mass-storage device (such as a magnetic or optical disk and its corresponding disk drive) may be used as the permanent storage device 1602.

In one or more implementations, a removable storage device (such as a floppy disk, flash drive, and its corresponding disk drive) may be used as the permanent storage device 1602. Like the permanent storage device 1602, the system memory 1604 may be a read-and-write memory device. However, unlike the permanent storage device 1602, the system memory 1604 may be a volatile read-and-write memory, such as random access memory. The system memory 1604 may store any of the instructions and data that one or more processing unit(s) 1612 may need at runtime. In one or more implementations, the processes of the subject disclosure are stored in the system memory 1604, the permanent storage device 1602, and/or the ROM 1610. From these various memory units, the one or more processing unit(s) 1612 retrieves instructions to execute and data to process in order to execute the processes of one or more implementations.

The bus 1608 also connects to the input and output device interfaces 1614 and 1606. The input device interface 1614 enables a user to communicate information and select commands to the electronic system 1600. Input devices that may be used with the input device interface 1614 may include, for example, microphones, alphanumeric keyboards and pointing devices (also called “cursor control devices”). The output device interface 1606 may enable, for example, the display of images generated by electronic system 1600. Output devices that may be used with the output device interface 1606 may include, for example, printers and display devices, such as a liquid crystal display (LCD), a light emitting diode (LED) display, an organic light emitting diode (OLED) display, a flexible display, a flat panel display, a solid state display, a projector, a speaker or speaker module, or any other device for outputting information. One or more implementations may include devices that function as both input and output devices, such as a touchscreen. In these implementations, feedback provided to the user can be any form of sensory feedback, such as visual feedback, auditory feedback, or tactile feedback; and input from the user can be received in any form, including acoustic, speech, or tactile input.

Finally, as shown in FIG. 16, the bus 1608 also couples the electronic system 1600 to one or more networks and/or to one or more network nodes through the one or more network interface(s) 1616. In this manner, the electronic system 1600 can be a part of a network of computers (such as a LAN, a wide area network (“WAN”), or an Intranet, or a network of networks, such as the Internet. Any or all components of the electronic system 1600 can be used in conjunction with the subject disclosure.

In accordance with some aspects of the subject disclosure, a method is provided that includes operating a speaker to output at least a first tone in a human audible frequency range and a second tone configured as a human inaudible tone; identifying an amount of an intermodulation distortion generated by the at least the first tone and the second tone; determining an excursion of a sound-generating element of the speaker based on the amount of the intermodulation distortion; and controlling the speaker based in part on the determined excursion.

In accordance with other aspects of the subject disclosure, an electronic device is provided that includes a speaker and control circuitry configured to: operate the speaker to output at least a first tone in a human audible frequency range and a second tone configured as a human inaudible tone; identify an amount of an intermodulation distortion generated by the at least the first tone and the second tone; determine an excursion of a sound-generating element of the speaker based on the amount of the intermodulation distortion; and control the speaker based in part on the determined excursion.

In accordance with other aspects of the subject disclosure, a non-transitory machine-readable medium is provided, storing instructions which, when executed by one or more processors, cause the one or more processors to perform operations that include: operating a speaker to output at least a first tone in a human audible frequency range and a second tone configured as a human inaudible tone; identifying an amount of an intermodulation distortion generated by the at least the first tone and the second tone; determining an excursion of a sound-generating element of the speaker based on the amount of the intermodulation distortion; and controlling the speaker based in part on the determined excursion.

Implementations within the scope of the present disclosure can be partially or entirely realized using a tangible computer-readable storage medium (or multiple tangible computer-readable storage media of one or more types) encoding one or more instructions. The tangible computer-readable storage medium also can be non-transitory in nature.

The computer-readable storage medium can be any storage medium that can be read, written, or otherwise accessed by a general purpose or special purpose computing device, including any processing electronics and/or processing circuitry capable of executing instructions. For example, without limitation, the computer-readable medium can include any volatile semiconductor memory, such as RAM, DRAM, SRAM, T-RAM, Z-RAM, and TTRAM. The computer-readable medium also can include any non-volatile semiconductor memory, such as ROM, PROM, EPROM, EEPROM, NVRAM, flash, nvSRAM, FeRAM, FeTRAM, MRAM, PRAM, CBRAM, SONOS, RRAM, NRAM, racetrack memory, FJG, and Millipede memory.

Further, the computer-readable storage medium can include any non-semiconductor memory, such as optical disk storage, magnetic disk storage, magnetic tape, other magnetic storage devices, or any other medium capable of storing one or more instructions. In one or more implementations, the tangible computer-readable storage medium can be directly coupled to a computing device, while in other implementations, the tangible computer-readable storage medium can be indirectly coupled to a computing device, e.g., via one or more wired connections, one or more wireless connections, or any combination thereof.

Instructions can be directly executable or can be used to develop executable instructions. For example, instructions can be realized as executable or non-executable machine code or as instructions in a high-level language that can be compiled to produce executable or non-executable machine code. Further, instructions also can be realized as or can include data. Computer-executable instructions also can be organized in any format, including routines, subroutines, programs, data structures, objects, modules, applications, applets, functions, etc. As recognized by those of skill in the art, details including, but not limited to, the number, structure, sequence, and organization of instructions can vary significantly without varying the underlying logic, function, processing, and output.

While the above discussion primarily refers to microprocessor or multi-core processors that execute software, one or more implementations are performed by one or more integrated circuits, such as ASICs or FPGAs. In one or more implementations, such integrated circuits execute instructions that are stored on the circuit itself.

Various functions described above can be implemented in digital electronic circuitry, in computer software, firmware or hardware. The techniques can be implemented using one or more computer program products. Programmable processors and computers can be included in or packaged as mobile devices. The processes and logic flows can be performed by one or more programmable processors and by one or more programmable logic circuitry. General and special purpose computing devices and storage devices can be interconnected through communication networks.

Some implementations include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, ultra density optical discs, any other optical or magnetic media, and floppy disks. The computer-readable media can store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some implementations are performed by one or more integrated circuits, such as application specific integrated circuits (ASICs) or field programmable gate arrays (FPGAs). In some implementations, such integrated circuits execute instructions that are stored on the circuit itself.

As used in this specification and any claims of this application, the terms “computer”, “processor”, and “memory” all refer to electronic or other technological devices. These terms exclude people or groups of people. For the purposes of the specification, the terms “display” or “displaying” means displaying on an electronic device. As used in this specification and any claims of this application, the terms “computer readable medium” and “computer readable media” are entirely restricted to tangible, physical objects that store information in a form that is readable by a computer. These terms exclude any wireless signals, wired download signals, and any other ephemeral signals.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some implementations, multiple software aspects of the subject disclosure can be implemented as sub-parts of a larger program while remaining distinct software aspects of the subject disclosure. In some implementations, multiple software aspects can also be implemented as separate programs. Finally, any combination of separate programs that together implement a software aspect described here is within the scope of the subject disclosure. In some implementations, the software programs, when installed to operate on one or more electronic systems, define one or more specific machine implementations that execute and perform the operations of the software programs.

A computer program (also known as a program, software, software application, script, or code) can be written in any form of programming language, including compiled or interpreted languages, declarative or procedural languages, and it can be deployed in any form, including as a standalone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Some of the blocks may be performed simultaneously. For example, in certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

The predicate words “configured to”, “operable to”, and “programmed to” do not imply any particular tangible or intangible modification of a subject, but, rather, are intended to be used interchangeably. For example, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as an “aspect” does not imply that such aspect is essential to the subject technology or that such aspect applies to all configurations of the subject technology. A disclosure relating to an aspect may apply to all configurations, or one or more configurations. A phrase such as an aspect may refer to one or more aspects and vice versa. A phrase such as a “configuration” does not imply that such configuration is essential to the subject technology or that such configuration applies to all configurations of the subject technology. A disclosure relating to a configuration may apply to all configurations, or one or more configurations. A phrase such as a configuration may refer to one or more configurations and vice versa.

The word “example” is used herein to mean “serving as an example or illustration.” Any aspect or design described herein as “example” is not necessarily to be construed as preferred or advantageous over other aspects or design.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f), unless the element is expressly recited using the phrase “means for” or, in the case of a method claim, the element is recited using the phrase “step for.” Furthermore, to the extent that the term “include,” “have,” or the like is used in the description or the claims, such term is intended to be inclusive in a manner similar to the term “comprise” as “comprise” is interpreted when employed as a transitional word in a claim.

What is claimed is:

1. A method, comprising:
operating a speaker to output at least a first tone in a human audible frequency range and a second tone configured as a human inaudible tone;
identifying an amount of an intermodulation distortion generated by the at least the first tone and the second tone;
determining an excursion of a sound-generating element of the speaker based on the amount of the intermodulation distortion; and
controlling the speaker based in part on the determined excursion.

2. The method of claim 1, wherein:
the second tone comprises at least one of:
a tone in a human inaudible frequency range, or
a tone in the human audible frequency range and having an amplitude that is below a human audibility threshold amplitude.

3. The method of claim 2, wherein the at least the first tone comprises a single tone in the human audible frequency range or a sweep of tones in the human audible frequency range.

4. The method of claim 2, wherein the at least the first tone comprises a tone of a plurality of tones corresponding to media content being output by the speaker.

5. The method of claim 1, wherein the controlling comprises modifying an output of the speaker to prevent the excursion from exceeding a predetermined maximum excursion for speaker protection.

6. The method of claim 1, wherein the controlling comprises adjusting audio content being output by the speaker to correct for a speaker non-linearity.

7. The method of claim 1, wherein the amount of the intermodulation distortion comprises an amplitude of a first intermodulation distortion peak generated by the intermodulation distortion in a current passing through the speaker.

8. The method of claim 7, further comprising:
identifying a peak-to-dip amplitude of a second intermodulation distortion peak generated by the intermodulation distortion in the current passing through the speaker;
determining a rocking characteristic of the sound-generating element based on the peak-to-dip amplitude; and
controlling the speaker based on the excursion and the rocking characteristic.

9. The method of claim 8, wherein the first intermodulation distortion peak is a second order peak, and wherein the second intermodulation distortion peak is a third order peak.

10. The method of claim 8, further comprising:
determining a force factor of the speaker based on the intermodulation distortion generated by the at least the first tone and the second tone; and
controlling the speaker based on the excursion, the rocking characteristic, and the force factor.

11. The method of claim 1, wherein determining the excursion of the sound-generating element of the speaker based on the amount of the intermodulation distortion comprises:
obtaining an amplitude of an intermodulation distortion peak in an output current from the speaker; and
applying a speaker-specific gain factor for the speaker to the amplitude of the intermodulation distortion peak in the output current to obtain the excursion.

12. The method of claim 1, further comprising:
detecting an impact of a component of the speaker based on the amount of the intermodulation distortion.

13. The method of claim 12, wherein detecting the impact of a component of the speaker based on the amount of the intermodulation distortion comprises detecting the impact of a component of the speaker based on an amplitude of a peak, having an order that is fourth order or higher than fourth order, in the intermodulation distortion.

14. An electronic device, comprising:
a speaker; and
control circuitry configured to:
operate the speaker to output at least a first tone in a human audible frequency range and a second tone configured as a human inaudible tone;
identify an amount of an intermodulation distortion generated by the at least the first tone and the second tone;
determine an excursion of a sound-generating element of the speaker based on the amount of the intermodulation distortion; and
control the speaker based in part on the determined excursion.

15. The electronic device of claim 14, wherein the at least the first tone comprises at least one of: a single tone in the human audible frequency range, a sweep of tones in the human audible frequency range, or a tone of a plurality of tones corresponding to media content being output by the speaker.

16. The electronic device of claim 14, wherein the amount of the intermodulation distortion comprises an amplitude of a first intermodulation distortion peak generated by the intermodulation distortion in a current passing through the speaker.

17. The electronic device of claim 16, wherein the control circuitry is further configured to:
identify a peak-to-dip amplitude of a second intermodulation distortion peak generated by the intermodulation distortion in the current passing through the speaker;
determine a rocking characteristic of the sound-generating element based on the peak-to-dip amplitude; and
control the speaker based on the excursion and the rocking characteristic.

18. The electronic device of claim 17, wherein the first intermodulation distortion peak is a second order peak, and wherein the second intermodulation distortion peak is a third order peak.

19. The electronic device of claim 16, wherein the control circuitry is configured to determine the excursion of the sound-generating element of the speaker based on the amount of the intermodulation distortion by:
obtaining an amplitude of an intermodulation distortion peak in an output current from the speaker; and
applying a speaker-specific gain factor for the speaker to the amplitude of the intermodulation distortion peak in the output current to obtain the excursion.

20. A non-transitory machine-readable medium storing instructions which, when executed by one or more processors, cause the one or more processors to perform operations comprising:
operating a speaker to output at least a first tone in a human audible frequency range and a second tone configured as a human inaudible tone;
identifying an amount of an intermodulation distortion generated by the at least the first tone and the second tone;
determining an excursion of a sound-generating element of the speaker based on the amount of the intermodulation distortion; and
controlling the speaker based in part on the determined excursion.

21. The non-transitory machine-readable medium of claim 20, wherein the at least the first tone comprises at least one of: a single tone in the human audible frequency range, a sweep of tones in the human audible frequency range, or a tone of a plurality of tones corresponding to media content being output by the speaker.

22. The non-transitory machine-readable medium of claim 20, wherein the amount of the intermodulation distortion comprises an amplitude of a first intermodulation distortion peak generated by the intermodulation distortion in a current passing through the speaker.
